(19) United States
(12) Patent Application Publication
(10) Pub. No.: US 2012/0154181 A1
(43) Pub. Date: Jun. 21, 2012

(54) METHOD AND APPARATUS FOR INPUTTING KEY

(75) Inventor: Bong-Jae Rhee, Suwon-si (KR)

(73) Assignee: SAMSUNG ELECTRONICS CO., LTD., Suwon-si (KR)

(21) Appl. No.: 13/326,200

(22) Filed: Dec. 14, 2011

(30) Foreign Application Priority Data
Dec. 20, 2010 (KR) 10-2010-0131050

(51) Int. Cl. H03M 11/02

(52) U.S. Cl. 341/26

(57) ABSTRACT

A key input method and apparatus allow efficient typing on a keypad. A pressing of a first key followed by a pressing of a second key is detected. One of input values corresponding to one of the first and second keys is selected according to the other key of the first and second keys. The selected input value is entered as a key input.

### CROSS-REFERENCE TO RELATED APPLICATION(S) AND CLAIM OF PRIORITY

The present application is related to and claims priority under 35 U.S.C. §119(a) to a Korean Patent Application filed in the Korean Intellectual Property Office on Dec. 20, 2010 and assigned Serial No. 10-2010-0131050, the contents of which are incorporated herein by reference.

### TECHNICAL FIELD OF THE INVENTION

The present invention relates to key input, and more particularly, to a method and apparatus for inputting a key easily and quickly.

### BACKGROUND OF THE INVENTION

In general, a terminal is an electronic device that enables voice and data communication. Along with the diversification and development of mobile communication environments, portable terminals have been proliferated and used in a wide range of fields beyond voice calls.

A variety of functions that a portable terminal is capable of include Audio On Demand (AOD) and Video On Demand (VOD) services, real-time video calls through a camera equipped in the portable terminal, download and play of a game application, and Digital Multimedia Broadcasting (DMB) service through a DMB receiver.

To efficiently use such a portable terminal, the portable terminal is controlled through a plurality of key inputs.

A user inputs a key on a keypad or a virtual keyboard displayed on a touch screen, to thereby control his or her portable terminal. For example, the user may write a text message or a memo, may post to a connected Web page, or may enter a specific keyword to search for content within the portable terminal, through the keypad or the touch screen.

Due to portability at the sacrifice of size, a portable terminal has a keypad or a touch screen of a limited size. Accordingly, a minimum number of keys are provided on the keypad or the virtual keyboard and each key is mapped to a plurality of input values.

Conventionally, when a plurality of input values are assigned to a single key, one of the input values is selected by pressing the same key multiple times. As a result, much time is taken to input a key.

To solve the above problem, a QWERTY keypad is used. Despite convenient key inputs owing to the same key layout as the keyboard of a PC, the QWERTY keypad is not so convenient for the portable terminal. For instance, if the QWERTY keypad is configured in hardware, the area of the QWERTY keypad increases the size and weight of the portable terminal, thereby decreasing the portability of the portable terminal. Even though the QWERTY keypad is provided in the form of a virtual keyboard through a touch screen function, each key of the QWERTY keypad is small due to the limited size of a display in the portable terminal. Thus, it is difficult to press a key without affecting an adjacent key and a number of unintended keys may be input.

Accordingly, there exists a need for a method for enabling fast and convenient key inputs by improving the conventional key input method.

### SUMMARY OF THE INVENTION

To address the above-discussed deficiencies of the prior art, it is a primary object to provide at least the advantages described below. Accordingly, an aspect of embodiments of the present invention is to provide a method and apparatus for enabling fast and convenient key inputs in a portable terminal.

Conventionally, a character is selected and input by pressing one key at a time, apart from special keys such as “Shift” or “Ctrl”.

The present invention relates to a method for selecting and inputting a character by a combination of two pressed keys, one of which is pressed earlier than the other key in a portable terminal. Because the conventional key method that inputs a character by pressing one key is part of the key input method of the present invention that allows simultaneous key-down of two keys, the latter is compatible with the former. Accordingly, a user familiar with the conventional key input method can also use a portable terminal conveniently to which the present invention is applied. Since a character is selected by pressing another key while one key is pressed in the present invention, text input is faster than in the conventional key input method in which the character is input by pressing a key multiple times.

In accordance with an embodiment of the present invention, there is provided a key input method. A pressing of a first key followed by a pressing of a second key is detected. One of input values corresponding to one of the first and second keys is selected according to the other key of the first and second keys. The selected input value is entered as a key input.

In accordance with another embodiment of the present invention, there is provided a key input apparatus. A controller detects a pressing of a first key followed by a pressing of a second key, selects one of input values assigned to one of the first and second keys according to the other key of the first and second keys, and enters the selected input value as a key input.

In accordance with yet another embodiment of the present invention, there is provided a key input method. When a pressing of a second key while a first key is pressed is detected, a multi-key input mode is entered. One of input values corresponding to one of the first and second keys is selected according to the other key of the first and second keys. The selected input value is entered as a key input.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a block diagram of a portable terminal according to an embodiment of the present invention;

FIGS. 2A and 2B illustrate a difference between a conventional key input method and a key input method according to an embodiment of the present invention;

FIG. 3A is a flowchart illustrating a key input operation according to an embodiment of the present invention;

FIG. 3B is a flowchart illustrating a key input operation according to another embodiment of the present invention;

FIGS. 4A and 4B are views illustrating key input operations according to embodiments of the present invention;

FIGS. 5A and 5B are other views illustrating key input operations according to an embodiment of the present inventions;

FIGS. 6A and 6B are tables comparing a conventional key input method with the key input method according to an embodiment of the present invention;

FIGS. 7A and 7B are other views illustrating the key input operations according to embodiments of the present invention;

FIG. 8 illustrates key mapping when keys are input on a touch screen as illustrated in FIGS. 4A and 4B according to an embodiment of the present invention;

FIG. 9 is a view illustrating a key input on a touch screen according to an embodiment of the present invention; and

FIG. 10 is another view illustrating a key input on the touch screen according to an embodiment of the present invention.

Throughout the drawings, the same drawing reference numerals will be understood to refer to the same elements, features and structures.

### DETAILED DESCRIPTION OF THE INVENTION

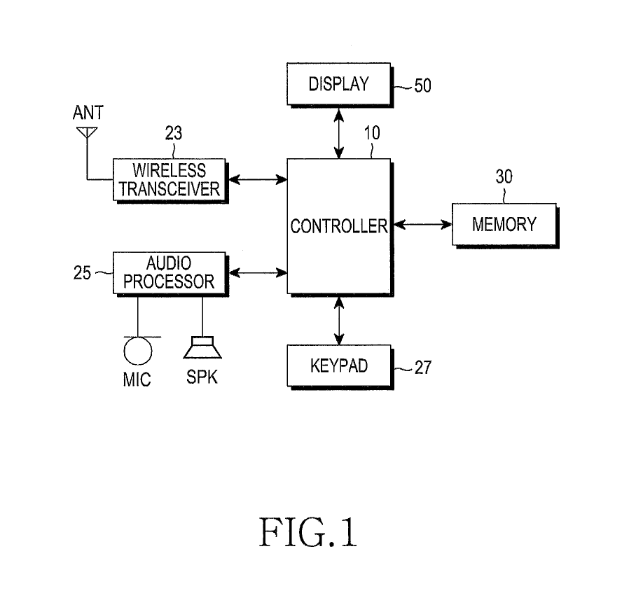

FIGS. 1 through 10, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged key input-enabled electronic device. Reference will now be made in detail to the preferred embodiments of the present invention with reference to the accompanying drawings.

FIG. 1 is a block diagram of a portable terminal according to an embodiment of the present invention. While the present invention related to key input is applicable to any key input-enabled electronic device, it is assumed that the present invention is implemented through a portable terminal that utilizes more convenient key inputs. In accordance with the embodiment of the present invention, the portable terminal is a mobile electronic device which is easy to carry. The term “portable terminal” covers a broad range of terminals including a mobile phone (e.g. a feature phone), a smart phone, an International Mobile Telecommunications (IMT)-2000 terminal, a Wideband Code Division Multiple Access (WCDMA) terminal, a Personal Digital Assistant (PDA), a Portable Multimedia Player (PMP), a DMB terminal, a Personal Computer (PC) like a desktop computer and a laptop computer, and such, to which the scope of the present invention is not limited.

While the portable terminal is shown in FIG. 1 without certain components such as a Global Positioning System (GPS) module, a camera module, a Bluetooth module, a Wireless Fidelity (Wi-Fi) module, an acceleration sensor, a proximity sensor, and a Digital Multimedia Broadcasting (DMB) receiver, it is clearly understood to those skilled in the art that they may be included in the portable terminal and provide their own functions.

For instance, the acceleration sensor senses the movement state of the portable terminal by measuring dynamic force such as acceleration, vibration, impact, and such. The display direction of a display 50 of the portable terminal may be detected based on the sensed movement state of the portable terminal.

The proximity sensor senses approach of a user's body part toward the portable terminal. The sensed information of the proximity sensor may be used to prevent malfunction of the portable terminal when the portable terminal provides a touch screen function.

A gyroscope monitors dynamic rotation of the portable terminal. It may be used in conjunction with the acceleration sensor in order to sense rotational motion of the portable terminal along six axes such as up and down, back and forth, side by side, and x-, y- and z-axis rotations.

A wireless transceiver 23 includes a Radio Frequency (RF) unit and a modem. The RF unit includes an RF transmitter for upconverting the frequency of a transmission signal and amplifying the upconverted signal and an RF receiver for low-noise-amplifying a received signal and downconverting the frequency of the low-noise-amplified signal. The modem includes a transmitter for encoding and modulating the transmission signal and a receiver for demodulating and decoding the signal received from the RF unit.

According to the embodiment of the present invention, the wireless transceiver 23 conducts wireless communication to connect to a user-requested web page. For example, the wireless transceiver 23 transmits information about a Uniform Resource Location (URL) set by the user to a server. When accessing the URL, the wireless transceiver 23 may receive data of a connected web page.

An audio processor 25 may include a Coder-Decoder (CODEC). The CODEC includes a data CODEC and an audio CODEC. The data CODEC processes packet data and the audio CODEC processes an audio signal such as voice and a multimedia file. The audio processor 25 reproduces an audio signal by converting a digital audio signal received from the modem to an analog signal through the audio CODEC, or converts an analog audio signal generated from a microphone to a digital audio signal through the audio CODEC and transmits the digital audio signal to the modem. The CODEC may be configured separately or incorporated into a controller 10. Meanwhile, the audio processor may output multimedia audio data of a web page on the Internet to a speaker (SPK) or an earphone (not shown).

A keypad 27 may include alphanumerical keys for entering digits and characters, function keys for setting functions, and a touch sensor for receiving a key input made by a user's touch. If the display 50 is configured into a touch screen, the keypad 27 may be omitted or include a minimum number of keys. In this situation, the display 50 may take charge of a part of key input functions.

In the embodiment of the present invention, the keys of the keypad 27 may be arranged row by row (or column by column) according to the layout of the keys, and the keys of the keypad 27 are grouped on a row basis.

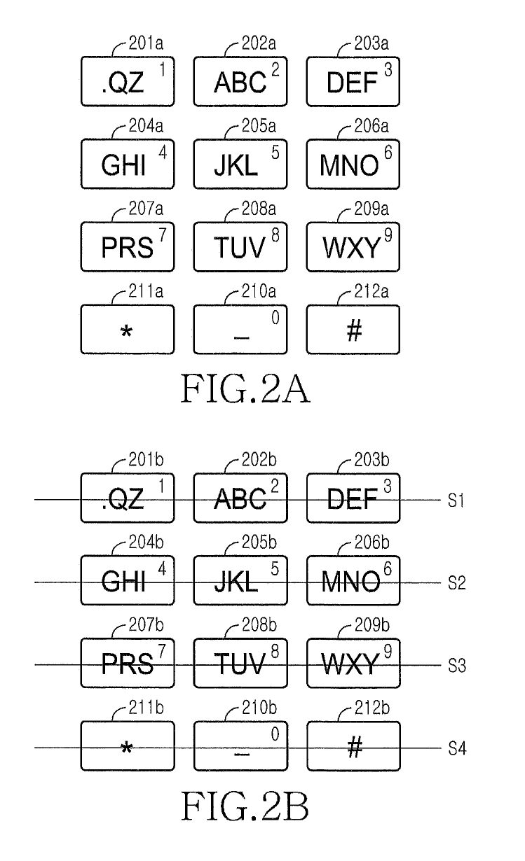

Referring to FIG. 2B, for example, keys 201b, 202b and 203b in the first row are grouped into a first group S1, keys 204b, 205b and 206b in the second row are grouped into a second group S2, keys 207b, 208b and 209b in the third row are grouped into a third group S3, and keys 211b, 210b and 212b in the fourth row are grouped into a fourth group S4 in the keypad 27 according to the embodiment of the present invention.

It is assumed that one or more input values are assigned to each key in the keypad 27. For instance, three input values A, B and C are assigned to the key 202b. Each key is mapped to a fourth input value corresponding to a number (e.g. ‘2’) in addition to three input values. For instance, the number (e.g. ‘2’) assigned to the key 202b or one of the three input values (A, B and C) corresponding to characters may be selected by means of a switch key (e.g. a number-character switch key). It may be further contemplated as another embodiment of the present invention that input values representing a number and characters are assigned to each key without a distinction between the number and the characters (i.e. without using the switch key). For example, the first to fourth input values A, B, C and ‘2’ may be assigned to the key 202b illustrated in FIG. 2B.

The keypad 27 according to the embodiment of the present invention will be described in greater detail in conjunction with a description of embodiments of the present invention related to key input.

A memory 30 may include a program memory and data memories. The program memory stores programs for controlling regular operations of the portable terminal. The memory 30 may include an external memory such as a Compact Flash (CF) memory card, a Secure Digital (SD) card, a micro-SD memory card, a mini-SD memory card, an eXtreme Digital (XD) card, and a memory stick.

The display 50 displays various types of information generated in the portable terminal 100. The display 50 may be various types of displays such as a Liquid Crystal Display (LCD), an Organic Light Emitting Diode (OLED) display (e.g. a Passive Matrix OLED (PMOLED) or Active Matrix OLED (AMOLED) display), and such. The display 50 may also include a touch screen that can be used not only as an output device but also as an input device along with the keypad 27. For example, the display 50 may provide the functions of zoom-in/zoom out, scroll, and screen switching for a web page according to a user's single-touch input or multi-touch input. The display 50 is suitable for the portable terminal, and thus the display 50 may support the resolutions of Quarter Video Graphic Array (QVGA, 240x320), Wide-screen QVGA (WQVGA, 400x240, 480x272, or 480x234), Enhanced Graphic Array (EGA, 640x400), VGA (640x480), Wide VGA (WVGA, 800x480), Super VGA (SVGA, 800x600), and Wide-Screen VGA (WSVGA, 1024x600), and such.

The controller 10 provides overall control to the portable terminal 100. The controller 10 may switch one operation of the portable terminal 100 to another operation according to a user input received through the keypad 27 or the display 50 and control the operations of the portable terminal 100.

A key click to enter a character on the display 50 or the keypad 27 may be divided into down-pressing of a key, that is, a key-down and releasing a finger from the key, that is, a key-up. Thus, the controller 10 performs a key input routine by detecting the key-down and key-up events. In most electronic devices such as a PC and a portable terminal, upon generation of a key-up, a key pressed until the key-up is generated is recognized and a character to be input is determined according to the key. Upon generation of an event of time-out of a predetermined time (or longer) from the key-down and the key-up, the controller 10 may perform the key-input routine. For example, if a key is kept pressed for a predetermined time or longer, the controller 10 performs successive key inputs or a hot key operation. If no key input follows the current key input for a predetermined time or longer, a cursor is shifted by one position.

In accordance with the embodiment of the present invention, the controller 10 monitors whether, while one key pressed, another key is input in the keypad 27. Upon detection of the following key input with the preceding key input in progress, the controller 10 controls input of one of input values assigned to the preceding input key in correspondence with the group number of the following input key, or controls input of one of input values assigned to the following input key in correspondence with the group number of the preceding input key.

FIGS. 2A and 2B illustrate the difference between a conventional key input method and a key input method according to an embodiment of the present invention.

Specifically, FIG. 2A illustrates the conventional key input method using a keypad with one or more input values assigned to each key, without any particular setting.

Referring to FIG. 2A, each of keys 201a to 212a is mapped to one or more input values.

For example, three input values representing characters D, E and F are assigned to the key 203a corresponding to a number input of ‘3’ and three input values representing characters P. R and S are assigned to the key 207a corresponding to a number input of ‘7’. A lot of key strokes are used to input a key on the keypad illustrated in FIG. 2A in a conventional manner, thereby taking a long time for the key input.

For example, to input “8” in the keypad illustrated in FIG. 2A, the key 207a should be clicked three times (three sets of key-downs and key-ups) in a character input mode (for inputting characters P, R and S). To be more specific, “P” is input by clicking (pressing) the key 207a once, “R” is input by clicking (pressing) the key 207a twice, and “S” is input by clicking (pressing) the key 207a three times, in the conventional key input method. This conventional key input method takes a long time for a key input. Moreover, when a user counts a wrong number of key clicks, an unintended character may be entered.

In contrast, FIG. 2B illustrates an embodiment of the present invention in which the key layout of the keypad is utilized to overcome the shortcoming of the conventional key input method. In general, keys are arranged in the form of a square in a keypad, and thus the keys can be divided into rows or columns.

Accordingly, referring to FIG. 2B, the keys 201b, 202b and 203b in the first row of the keypad are set as the first group, S1, the keys 204b, 205b and 206b in the second row are set as the second group, S2, the keys 207b, 208b and 209b in the third row are set as the third group, S3, and the keys 210b, 211b and 212b in the fourth row are set as the fourth group, S4 in the embodiment of the present invention.

While the keys are shown as grouped into four groups according to the 3×4 key layout of the keypad in FIG. 2B, group numbers may be changed according to the number and layout of keys. For example, for a 3×5 key layout, keys can be grouped into 5 groups. Alternatively or additionally, the keys may be grouped by the user. In addition, while only some frequently used keys of the keypad such as alphanumerical keys are shown in FIG. 2B, it is clearly understood to those skilled in the art that keys having special characters and function keys may further be provided to the keypad.

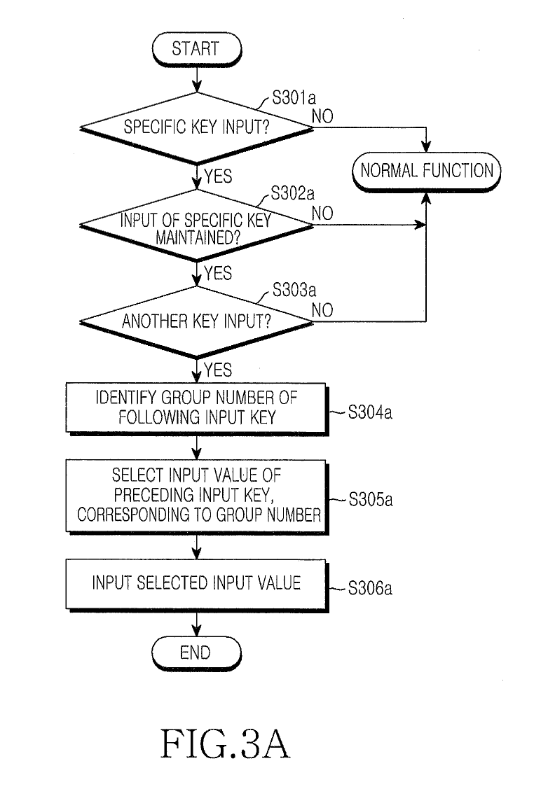

With reference to FIGS. 3A and 3B, key input methods using keys divided into a predetermined number of groups in a keypad will be described below.

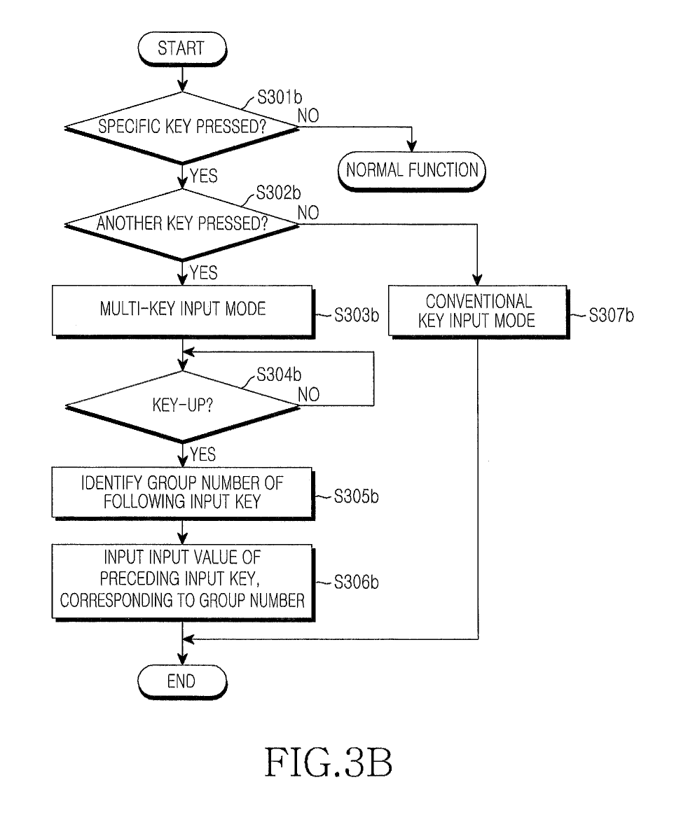

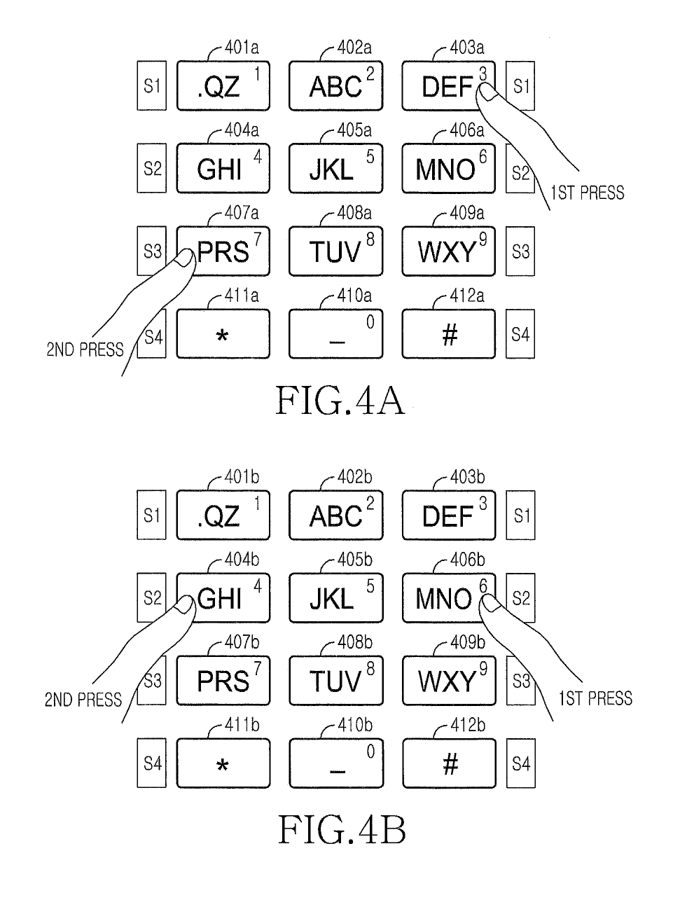

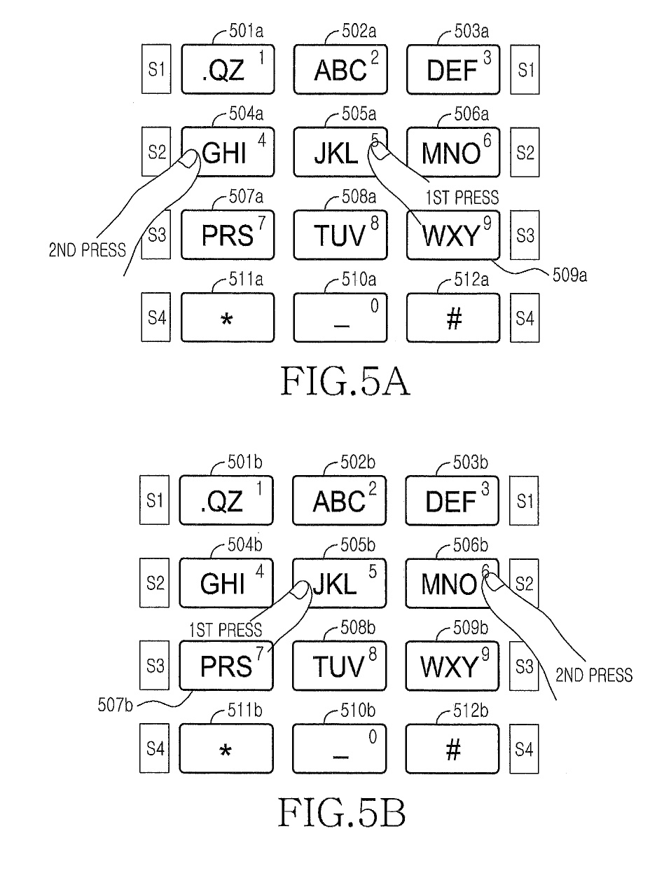

FIG. 3A is a flowchart illustrating a key input operation according to an embodiment of the present invention; FIG. 3B is a flowchart illustrating a key input operation according to another embodiment of the present invention; FIGS. 4A and 4B are views illustrating key input operations according to the embodiments of the present invention; FIGS. 5A and 5B are other views illustrating key input operations according to the embodiment of the present inventions; and FIGS. 6A and 6B are tables comparing a conventional key input method with the key input method according to an embodiment of the present invention.

As stated before, a key click involves a key-down and a key-up. In general, a corresponding value is input by a key-down and a key-input in one action, that is, the corresponding value is input by pressing and then releasing the key. For instance, a long key input function refers to execution of a predetermined function, when a key-down action of a key input lasts a predetermined time or longer.

The present invention may be implemented in two ways, that is, by making no distinction between a key-down and a key-up and by distinguishing between a key-down and a key-up. FIGS. 3A and 3B illustrate these two embodiments.

With reference to FIG. 3A, an embodiment of the present invention in which a key-down and a key-input are not distinguished from each other will be described below.

Referring to FIG. 3A, the controller monitors whether a specific key is input and then another key is input while the preceding key input is maintained in steps S301a, S302a and S303a.

Referring to FIG. 4A, in accordance with the embodiment of the present invention, the user first inputs a key 403a and then inputs a key 407a, while maintaining the preceding input key 403a in the input state. Thus, the user may request input of the third character F out of one or more characters D, E and F assigned to the key 403a, in correspondence with the group number of the following input key 407a.

Referring to FIG. 4B, the user first inputs a key 406b and then inputs a key 404b, while maintaining the preceding input key 406b in the input state. Thus, the user may request input of the second character N out of one or more characters M, N and 0 assigned to the key 406b, in correspondence with the group number of the following input key 404b.

Referring to FIG. 5A, the user may request input of the second character K out of one or more characters J, K and L assigned to a key 505a, in correspondence with the group number of a key 504a by first inputting the key 505a and then inputting the key 504a while maintaining the preceding input key 505a in the input state (i.e. while pressing the preceding input key 505a).

In comparison between the illustrated examples in FIGS. 5A and 5B, the same key input result is achieved using different following input keys. Referring to FIG. 5B, the user may request input of the second character K out of one or more characters J, K and L assigned to a key 505b, in correspondence with the group number of a key 506b by first inputting the key 505b and then inputting the key 506b while maintaining the preceding input key 505b in the input state.

That is, FIGS. 5A and 5B demonstrate achieving the same key input result with the same preceding key and different following keys. This is related to the group numbers of the following keys, which will be described below.

If with a preceding key in the input state, a following key is input, the controller checks the group number of the following key in step 304a.

Specifically, the controller 10 detects the group numbers of the following input keys 407a, 404b, 504a and 506b as ‘3’, ‘2’, ‘2’, and ‘2’, respectively in FIGS. 4A to 5B.

More specifically, the keys of the keypad 27 may be divided into a predetermined number of groups according to the layout of the keys in the key input-related embodiments of the present invention. As described before with reference to FIGS. 2A and 2B, if the keypad 20 (or a virtual keypads displayed on the display 50) has a 4×3 layout, the keys may be divided into four groups, row by row.

For example, the keys 201b, 202b and 203b in the first row of the keypad are set as the first group with group number ‘1’, S1, the keys 204b, 205b and 206b in the second row are set as the second group with group number ‘2’, S2, the keys 207b, 208b and 209b in the third row are set as the third group with group number ‘3’, S3, and the keys 210b, 211b and 212b in the fourth row are set as the fourth group with group number ‘4’, S4 in FIG. 2B. Likewise, in FIGS. 4A to 5B, keys 401a to 403a, 401b to 403b, 501a to 503a, and 501b to 503b are set as first groups with group number ‘1’, S1, keys 404a to 406a, 404b to 406b, 504a to 506a, and 504b to 506b are set as second groups with group number ‘2’, S2, keys 407a to 409a, 407b to 409b, 507a to 509a, and 507b to 509b are set as third groups with group number ‘3’, S3, and keys 410a to 412a, 410b to 412b, 510a to 512a, and 510b to 512b are set as fourth groups with group number ‘4’, S4.

In steps 305a and 306a, the controller 10 selects an input value corresponding to the group number of the following input key from among the input values of the preceding input key and controls input of the selected input value.

In FIG. 4A, upon detection of input of the key 403a followed by input of the key 407a and detection of the group number of the following input key 407a as 3, the controller 10 controls input of the third input value F out of the input values D, E and F assigned to the key 403a in correspondence with the group number ‘3’ of the key 407a. To input the third input value F of the key 403a, the key 408a or 409a having the same group number 3 may be input instead of the key 407a.

In FIG. 4B, upon detection of input of the key 406b followed by input of the key 404b and detection of the group number of the following input key 404b as ‘2’, the controller 10 controls input of the second input value N out of the input values M, N and assigned to the key 406b in correspondence with the group number ‘2’ of the key 404b. Since any following key will do for inputting the same character (e.g. N) so long as it has the same group number, the key 405b may be input instead of the key 404b.

In FIGS. 5A and 5B, while input of the key 505a or 505b is followed by input of the key 504a or 506b, the keys 504a and 506b have the same group number ‘2’. Therefore, the controller 10 controls input of the second input value K out of the input values J, K and L assigned to the key 505a or 505b in correspondence with the group number ‘2’.

The illustrated examples of FIGS. 5A and 5B are based on the assumption that the user inputs a key in the middle of the key layout and the user selects one of input values assigned to a preceding input key in two methods. That is, the user may request input of the character “K” out of the input values J, K and L assigned to the key 505a or 505b by inputting the key 504a (504b) or 506b (506a) in the second group with the group number ‘2’, S2 while inputting (pressing) the key 505a or 505b.

It may be further contemplated as a modification to the above embodiment of the present invention that if a plurality of other keys are input while a key is kept in an input state (i.e. kept pressed), input values of the following input keys are selected in correspondence with the group number of the preceding input key.

For example, referring to FIG. 4B, when the keys 401b, 407b, 407b and 401b are successively input with the key 406b in the input state, M, O, O and N are sequentially input. This scheme may be applied when the characters assigned to the key 406b are entered successively.

For example, referring to FIG. 4A, the user may enter “FLY” by inputting F by pressing the key 407a while maintaining the key 403a in the input state, and then pressing the keys 405a and 409a sequentially before releasing the key 407a.

While it has been described above that input values representing characters (e.g. J, K and L) are assigned to each key, it is also possible to assign an input value representing a number to the key.

For instance, it is assumed that input values J, K, L and ‘5’ are assigned to the key 405a or 405b in FIGS. 4A and 4B. Based on this assumption, “J” may be input by inputting the key 405a or 405b and then inputting a key of the group number 1, “K” may be input by inputting the key 405a or 405b and then inputting a key of the group number ‘2’, “L” may be input by inputting the key 405a or 405b and then inputting a key of the group number ‘3’, and “5” may be input by inputting the key 405a or 405b and then inputting a key of the group number ‘4’.

The modification of the embodiment of the present invention can provide a key input method for facilitating input of a number and a character without using a number-character switch key.

The difference between the embodiments of FIGS. 3A and 3B lies in whether a key input is processed by separating a key-down from a key-up.

According to the embodiment of the present invention, when another key is pressed while a key is kept in the key-down state, that is, kept pressed, one of the input values of the preceding input key is selected in correspondence with the group number of the following input key, without identifying the input of the following key as a key-down input (an input of the following key by pressing it) or as a key-up input (an input of the following key by pressing and then releasing it).

For example, the input of the following key may be divided into a key-down of the following key by continuous pressing (a key-down input) and a key-down and then key-up of the following key (a key-down & key-up input). In the embodiment of the present invention illustrated in FIG. 3A, both a key-down and a key-down & key-up are handled as a key input request.

Another embodiment of the present invention related to key input will be described with reference to FIG. 3B.

Referring to FIG. 3B, in steps S301b, S302b and S303b, if a key is first input by pressing it and then another key is input while the key is still pressed, the controller 10 enters a multi-key input mode. Otherwise, the controller 10 enters a conventional key input mode.

Specifically, when two keys are pressed with a specific time gap and are kept in the key-down state (e.g. both the preceding and following keys are kept pressed), the controller 10 enters the multi-key input mode. In contrast, if only one key is pressed (i.e. a key-down input) or if a key is pressed but not kept pressed (i.e. a key-up input) before the following key is pressed, the controller 10 enters the conventional key input mode.

In an embodiment of the present invention, one of the multi-key input mode and the conventional key input mode may be selected by a predetermined menu setting.

In steps S304b, S305b and S306b, upon detection of a key-up input of one of the preceding and following keys that have been input by being pressed, the controller 10 identifies the group number of the following input key and inputs one of input values of the preceding input key, corresponding to the group number of the following input key.

Steps S304b, S305b, and S306b are performed similarly to steps S304a, S305a and S306a of FIG. 3A, except that if a key-up input is generated from either of the preceding and following keys that have been input by being pressed is, the controller 10 determines that a key input request has been received from the user.

That is, if another key is input for selection of an input value by pressing it after a preceding key is pressed, the multi-key input mode is entered. If the user releases either of the pressed preceding and following keys (e.g. a key-up input), an input value of the preceding input key corresponding to the group number of the following input key is input in the second embodiment of the present invention. In other words, the corresponding value of the preceding key is not entered until a key-up is detected.

Referring to FIG. 4A, when pressed input of the key 403a is followed by pressed input of the key 407a while key 403a is still in the key-down state, the controller 10 enters the multi-key input mode. Then when the user releases one of the pressed keys 403a and 407a, the controller 10 identifies the group number of the key 407a as ‘3’ and inputs the third input value F out of the input values D, E and F assigned to the key 403a in correspondence with the group number ‘3’.

While it has been described in the first and second embodiments of the present invention illustrated in FIGS. 3A and 3B that an input value of a preceding input key is selected based on a following input key, there are alternative approaches. For example, embodiments of the present invention may be modified such that an input value of the following input key is selected based on the preceding input key.

As described above, a key can be quickly input by simultaneous inputs of keys in the embodiments of the present invention. With reference to FIGS. 6A and 6B, the conventional key input method will be compared with the embodiments of the present invention.

Referring to FIG. 6A, if the user intends to enter “I LOVE YOU”, the conventional key input method requires ‘24’ key inputs (e.g. ‘24’ key-downs and ‘24’ key-ups), whereas the present invention requires ‘15’ key inputs (e.g. ‘15’ key-downs and ‘15’ key-ups). Referring to FIGS. 2A and 6A, in the conventional key input method, the user inputs “I” by pressing the key 204a corresponding to number ‘4’ three times (three key-downs and three key-ups), space by pressing the key 210a once (one key-down and one key-up), “L” by pressing the key 205a corresponding to number ‘5’ three times (three key-downs and three key-ups), “O” by pressing the key 206a corresponding to number ‘6’ three times (three key-downs and three key-ups), “V” by pressing the key 208a corresponding to number ‘8’ three times (three key-downs and three key-ups), “E” by pressing the key 203a corresponding to number ‘3’ twice (two key-downs and two key-ups), space by pressing the key 210a once (one key-down and one key-up), “Y” by pressing the key 209a corresponding to number ‘9’ three times (three key-downs and three key-ups), “O” by pressing the key 206a corresponding to number ‘6’ three times (three key-downs and three key-ups),and “U” by pressing the key 205a corresponding to number ‘5’ twice (two key-downs and two key-ups).

Referring to FIGS. 2B and 6A, in the key input method according to the embodiment of the present invention, when pressed input of the key 204b corresponding to number ‘4’ is followed by pressed input of the key 209b corresponding to number ‘9’ and then a key-up occurs to one of the pressed keys 204b and 209b, the third input value “I” of the preceding input key 204b is input. Herein, instead of the following key 209b, the key 207b or 208b having the same group number ‘3’ may be input by being pressed. For example, if the pressed input of the key 204b is followed by the pressed input of the key 209b and either of the pressed keys 204b and 209b is released (i.e. a key-up), the third input value “I” of the key 204b is input.

Space is input by pressing and then releasing the key 201b corresponding to number ‘0’ (a key-down and then a key-up) in the conventional manner.

“L”, “O” and “V” are the third input values of the keys 205b, 206b and 208b, respectively. Therefore, to sequentially input the characters “L”, “O” and “V” in the embodiment of the present invention, while the key 205b is input by being pressed, the key 207b is input by being pressed to select the group number ‘3’ Then the pressed key 205b is released (i.e. a key-up), thus inputting “L”. Then, while the key 207b is kept pressed, the keys 206b and 208b are sequentially pressed and released (a key-down and then a key-up). Thus, “O” and “V” are input.

Then, the user may input “E”, space, “Y”, “O” and “U” according to the embodiment of the present invention.

Referring to FIG. 6B, when the user intends to input “MOMMY”, the conventional basic key input method requires nine key inputs (nine key-downs and nine key-ups) and three cursor shifts based on time-outs, OK key inputs, or directional key inputs, whereas the present invention requires seven key-downs and key-ups.

Referring to FIGS. 2A and 6B, in the conventional key input method, when the user wants to input “M” and “O” successively, the user inputs “M” by pressing and then releasing the key 206a corresponding number ‘6’ once (a key-down and a key-up), waits a predetermined time, t, or enters an OK key or enters a right directional key (denoted by “T.O” in FIG. 6B), and then inputs “O” by pressing the key 206a three times (three key-downs and three key-ups), because “M” and “O” are assigned to the same key 206a. To input “M” successively twice after inputting “O”, the user presses the key 206a after waiting the predetermined time, t, or entering the OK key or the right directional key, waits the predetermined time, t, or enters the OK key or the right directional key again, and then presses and releases the key 206a once (a key-down and a key-up). In summary, “MOMMY” can be input by three time-outs, t, or three inputs of the OK key or the right directional key (three key-downs and three key-ups) and nine key-downs and key-ups of the key having the input values in the conventional key input method.

Referring to FIGS. 2B and 6B, in the key input method according to the embodiment of the present invention, “MOMM” out of the word “MOMMY” can be input successively using the same key 206b. Thus, while the key 206b is kept pressed (a key-down), the keys 201b, 207b, 201b, and 201b are sequentially pressed and released (key-downs and key-ups). In this manner, input of “MOMM” requires only five key inputs (i.e. five key-downs and five key-ups). Subsequently, “Y” is input by pressing and then releasing the key 207b (a key-down and a key-up), while pressing the key 209b (a key down). In this manner, the word “MOMMY” is completely input.

In the present invention in which a key is input through preceding and following inputs, when the first input value of a specific key is to be input, the key has only to be input once as is done conventionally. For example, each of the first input values of some keys such as “.”, “A”, “D”, “G”, “J”, “M”, “P”, “T”, “W”, “*”, “-”, and “#” may be input through one key-down and key-up of a key as is done conventionally.

As described before with reference to FIGS. 6A and 6B, for the same input, the conventional key input method and the key input method according to the embodiment of the present invention differ in the number of key inputs and time taken for the input. Accordingly, the user can input a key quickly and easily in the key input method according to the embodiment of the present invention. The key input method according to the embodiment of the present invention is compatible with the conventional key input method because the former includes the latter. Therefore, only when a word composed of first characters assigned to keys is written, the same time according to the conventional key input method is taken. In any other situation, the key input method of the present invention enables faster key input than the conventional key input method.

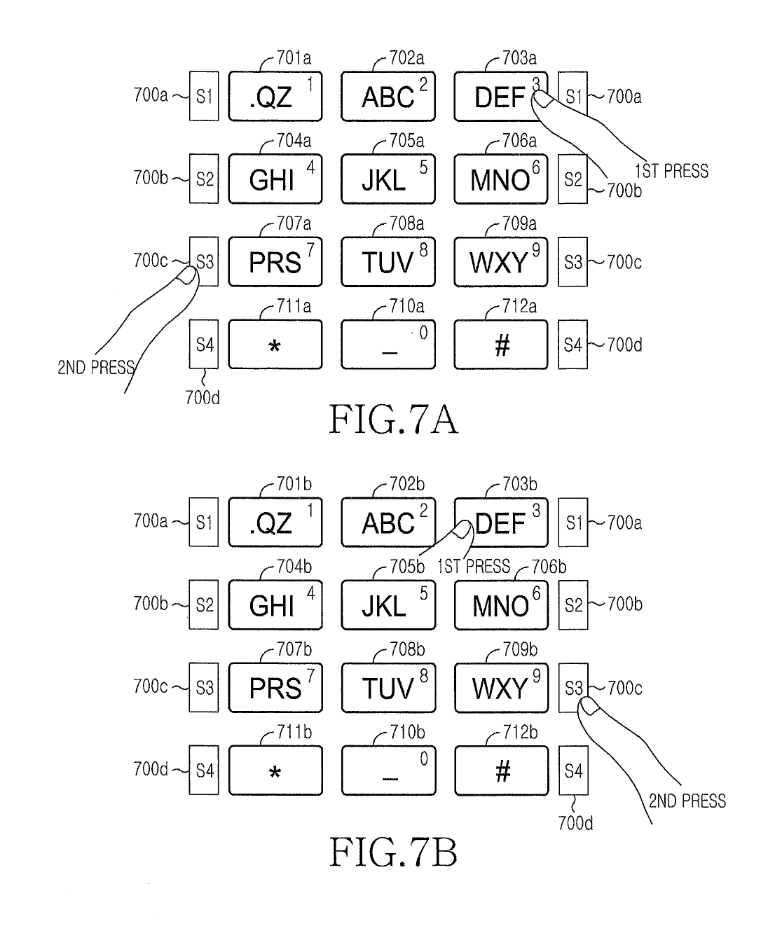

The advantages of the key input method of the present invention are also apparent in FIG. 8. FIG. 8 illustrates key mapping when keys are input on a touch screen as illustrated in FIGS. 4A and 4B according to an embodiment of the present invention. FIG. 8 compares the conventional key input method with the key input method according to the embodiment of the present invention, when characters are input using keys illustrated in FIGS. 4A and 4B.

Referring to FIG. 8, conventionally, an input value is selected according to the number of inputs of a key corresponding to the input value. For example, “A” is entered by inputting the key 402a once (one key-down and key-up), “B” by inputting the key 402a twice (two key-downs and key-ups), and “C” by inputting the key 402a three times (three key-downs and key-ups) in FIG. 4A. In contrast, one of a plurality of input values assigned to a specific key is selected according to a group key (or a group number selection key) in the present invention, as described before. It is apparently noted from the key mapping of FIG. 8 that a character can be entered by combining a preceding input key with a following input key (the preceding or following input key serves as the group key according to embodiments) as well as by clicking a key in the conventional manner. While “*” and “#” keys are not shown in FIG. 8, it is clearly understood that a plurality of characters can be mapped to each of these keys.

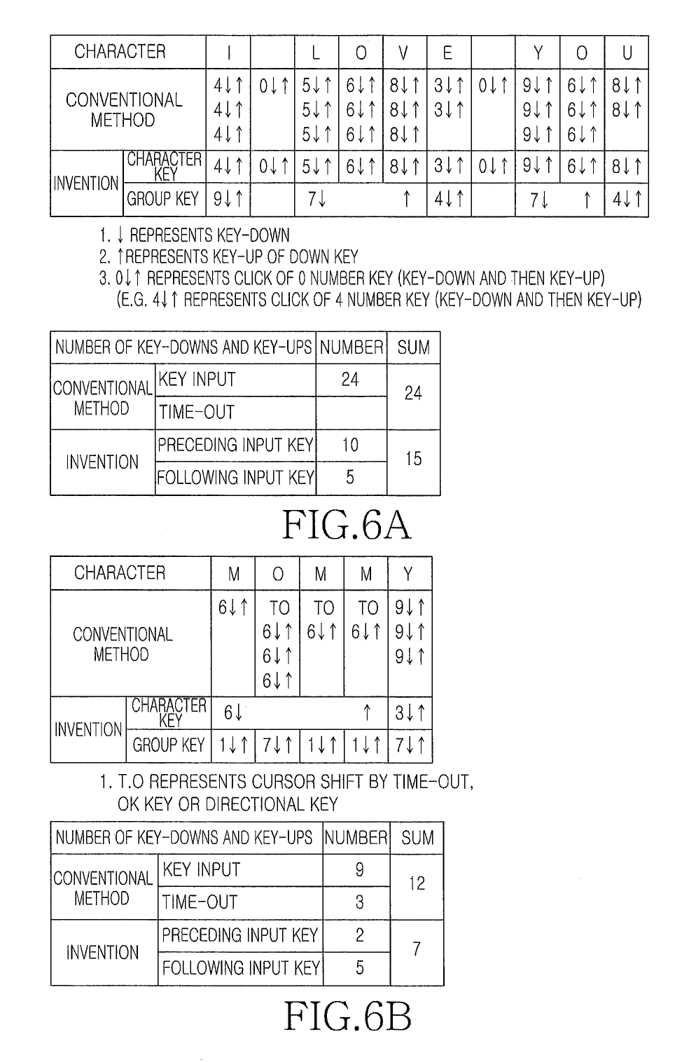

FIGS. 7A and 7B are other views illustrating the key input operations according to the embodiments of the present invention.

It has been described with reference to FIGS. 3A to 6 that one of input values assigned to a preceding input key is selected by a following input key and one or more input values are also assigned to the following input key. In FIGS. 7A and 7B, selection keys 700a to 700d are separately provided to select one of the input values assigned to a preceding input key (e.g. a preceding pressed key). For example, the user may request input of the third input value F of a key 703a in correspondence with the group number 3 of the key 700c by inputting the key 700c (including at least one of a key-down and a key-input) while pressing the key 703a.

While the selection keys 700a to 700d (e.g. group number setting or selection keys) may be configured in hardware, they are preferably configured in the form of virtual keys on a touch screen in terms of the portability of the portable terminal. The keys 401a to 412a and 401b to 412b of FIGS. 4A and 4B, the keys 501a to 512a and 501b to 512b of FIGS. 5A and 5B, and the keys 701a to 712a and 701b to 712b of FIGS. 5A and 5B may also be configured into a virtual keyboard displayed on a display that includes a touch screen function.

If the selection keys 700a to 700d are provided as virtual keys on the touch screen to select an input value of a preceding input key, these following input keys may be disposed on one side, rather than at both sides as illustrated in FIGS. 7A and 7B. In addition, the following input keys may be positioned freely by user request. If special keys such as function keys are positioned in an additional column in a keypad or keyboard, the following input keys 700a to 700d may be assigned to these special keys.

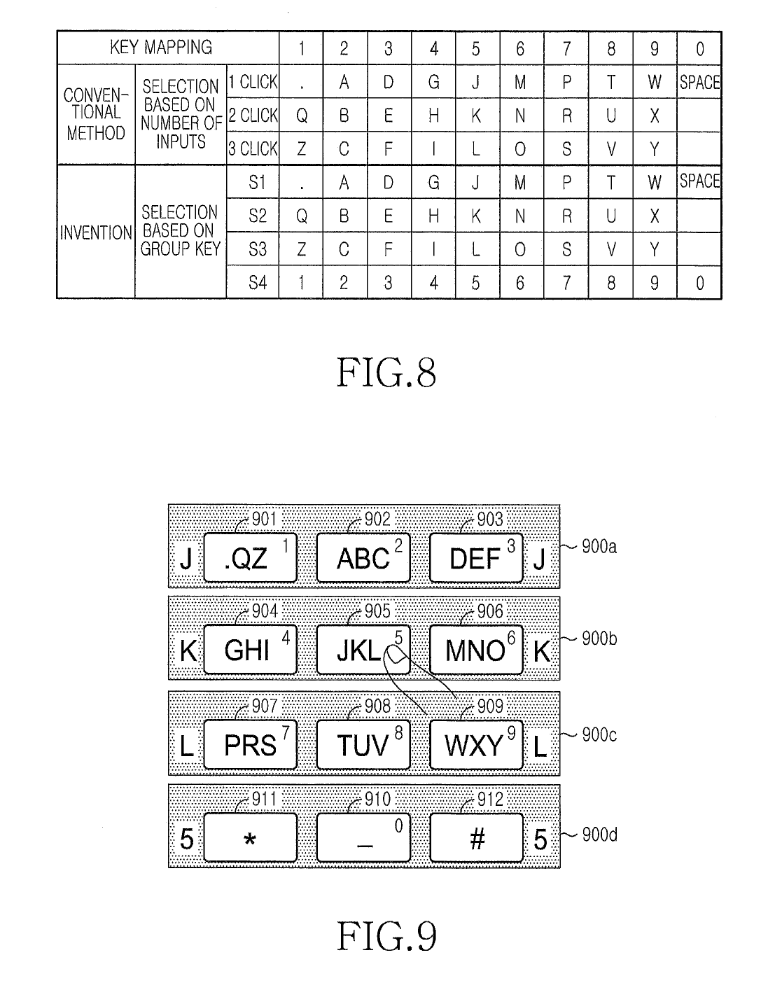

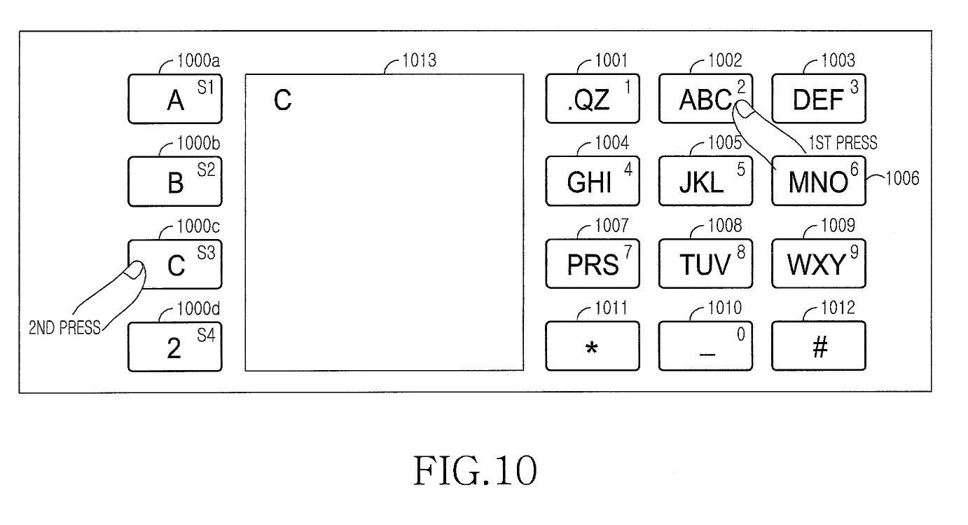

An embodiment of the present invention for application to virtual keys on a touch screen is illustrated in FIGS. 9 and 10. FIG. 9 is a view illustrating a key input on a touch screen according to an embodiment of the present invention, and FIG. 10 is another view illustrating a key input on the touch screen according to an embodiment of the present invention.

Referring to FIG. 9, a screen is displayed such that a user can readily input a key on the touch screen according to the present invention. When a specific key is pressed, available input values of this preceding input key that can be selected by a following input key corresponding to a group number are shown, as indicated by reference numerals 900a to 900d.

For instance, when a key 905 is first pressed, input values J, K, L and 5 assigned to this preceding input key 905 are shown along with keys corresponding to group numbers. Thus, the user can easily identify an input value to be selected from the key 905 by inputting a key corresponding to a specific group number.

For example, as the input values of the preceding input key 905, as indicated by 900a to 900d, are shown along with their matching group numbers, the user may request input of J by inputting one of keys 901, 902, and 903 having group number ‘1’, input of K by inputting one of keys 904, 905 and 906 having group number ‘2’, input of L by inputting one of keys 907, 908 and 909 having group number ‘3’, and input of 5 by inputting one of keys 910, 911 and 912 having group number ‘4’.

FIG. 10 illustrates an example of inputting a character, while grabbing a portable terminal equipped with a touch screen with both hands in landscape orientation.

Referring to FIG. 10, a character input screen 1013 is positioned at the center with a keypad that includes keys 1001 to 1012 at the right side and keys 1000a to 1000d for selecting group numbers S1 to S4 at the left side. The keys 1000a to 1000d may be general function keys and when one of the keys 1001 to 1012 is pressed, the keys 1000a to 1000d may switch to the group keys S1 to S4. The user presses a key having an intended character from among the keys 1001 to 1012 with the right hand and selects the intended character of the key by pressing one of the keys 1000a to 1000d with the left hand. For example, to input “C”, the user presses the key 1002 with the right hand. Then “A”, “B”, “C” and “2” are displayed on the keys 1000a to 1000d, respectively. Then the user selects “C” by inputting the key 1000c with the left hand. The selected “C” is displayed on the screen 1013. The screen layout illustrated in FIG. 10 is for a right-handed user. For a left-handed person, the screen layout may be changed by disposing the keys 1001 to 1012 at the left side and the keys 1000a to 1000d at the right side. Thus, the above-described key input operation may be performed by exchanging key inputs of the right hand with key inputs of the left hand.

While it has been described with reference to FIGS. 1 to 7B in the embodiments of the present invention that a character assigned to a preceding input key is selected by a following input key. However, the functions of preceding and following input keys may be swapped. That is, a user may first select a group number by pressing a specific key and then determine an input value by selecting a following input key to which an intended character is assigned. For example, referring to FIG. 4A, upon detection of input of the key 404a while the key 406a is pressed, the controller 10 identifies the group number of the preceding input key 406a and controls input of the second character assigned to the following input key 404a, “H”.

As is apparent from the above description of the present invention, a key can be input fast and easily in a portable terminal.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A key input method comprising:
detecting a pressing of a first key and then a pressing of a second key;
selecting one of input values corresponding to one of the first and second keys according to the other key of the first and second keys; and
entering the selected input value as a key input.

2. The key input method of claim 1, wherein detecting the pressing of the first key and then the pressing of the second key comprises detecting the pressing the second key while the first key is pressed.

3. The key input method of claim 1, wherein selecting one of the input values comprises:
determining a group number of the other key; and
selecting one of the input values corresponding to the one of the first and second keys according to the group number.

4. The key input method of claim 1, wherein the one of the first and second keys is the second key and the other key is the first key.

5. The key input method of claim 1, wherein the one of the first and second keys is the first key and the other key is the second key.

6. The key input method of claim 1, further comprising:
detecting a pressing of a third key while the other key is pressed, after the selected input value is entered as the key input; and
entering one of input values corresponding to the third key according to the other key.

7. The key input method of claim 6, wherein entering one of the input values corresponding to the third key comprises:
determining a group number of the other key; and
selecting one of the input values corresponding to the third key according to the group number.

8. A key input apparatus comprising:
a controller configured to, detect a pressing of a first key followed by a pressing of a second key, select one of input values corresponding to one of the first and second keys according to the other key of the first and second keys, and enter the selected input value as a key input.

9. The key input apparatus of claim 8, wherein the controller is further configured to detect the pressing of the second key while the first key is pressed.

10. The key input apparatus of claim 8, wherein the controller is further configured to determine a group number of the other key, and select one of the input values corresponding to the one of the first and second keys according to the group number.

11. The key input apparatus of claim 8, wherein the one of the first and second keys is the second key and the other key is the first key.

12. The key input apparatus of claim 8, wherein the one of the first and second keys is the first key and the other key is the second key.

13. The key input apparatus of claim 8, wherein the controller is further configured to detect a pressing of a third key while the other key is pressed after the selected input value is entered as the key input, and enter one of input values corresponding to the third key according to the other key.

14. The key input apparatus of claim 13, wherein the controller is further configured to determine a group number of the other key, and select one of the input values corresponding to the third key according to the group number.

15. A key input method comprising:
entering a multi-key input mode upon detecting a pressing of a second key while a first key is pressed;
selecting one of input values corresponding to one of the first and second keys according to the other key of the first and second keys; and
entering the selected input value as a key input.

16. The key input method of claim 15, wherein selecting one of the input values comprises:
determining a group number of the other key, when one of the first and second keys is released; and
selecting one of the input values corresponding to the oen of the first and second keys according to the group number.

17. The key input method of claim 16, wherein the released key is the second key.

18. The key input method of claim 16, wherein the released key is the first key.

19. The key input method of claim 16, further comprising:
detecting a pressing of a third key while the other key is still pressed after entering the selected input value; and
entering one of input values corresponding to the third key according to the group number as a subsequent key input.

20. The key input method of claim 16, further comprising:
detecting a pressing of a third key while the one of the first and second keys is still pressed after entering the selected input value;
determining a group number of the third key; and
entering one of the input values corresponding to the one of the first and second keys according to the group number as a subsequent key input.
